(19) United States
(12) Patent Application Publication
(10) Pub. No.: US 2026/0247961 A1
(43) Pub. Date: Aug. 20, 2026

(54) STRUCTURE AND FORMATION METHOD OF PACKAGE WITH THERMAL CONDUCTIVE STRUCTURE

(71) Applicant: Taiwan Semiconductor Manufacturing Company, Ltd., Hsinchu (TW)

(72) Inventors: Wen-Yun WANG, Taipei City (TW); Pu WANG, Hsinchu City (TW); Chao-Wen SHIH, Zhubei City (TW); Kuo-Chiang TING, Hsinchu City (TW); Yen-Ming CHEN, Chu-Pei City (TW)

(73) Assignee: Taiwan Semiconductor Manufacturing Company, Ltd., Hsinchu (TW)

(21) Appl. No.: 19/055,899

(22) Filed: Feb. 18, 2025

(51) Int. Cl. H01L 23/367; H01L 21/48; H01L 21/56; H01L 21/683; H01L 21/768; H01L 23/00; H01L 23/31; H01L 25/065

(52) U.S. Cl. CPC H10W 40/226; H10P 72/74; H10W 20/056; H10W 20/062; H10W 20/074; H10W 70/027; H10W 74/01; H10W 74/141; H10W 90/00; H10W 72/0198; H10W 74/10; H10W 80/312; H10W 80/327; H10W 90/792

(57) ABSTRACT

A package structure and a method for forming a package structure are provided. The method includes disposing an upper chip-containing structure over a lower chip-containing structure and forming a protective layer laterally surrounding the upper chip-containing structure. The method also includes partially removing the protective layer to form an opening extending towards the lower chip-containing structure. The method further includes forming a thermal conductive structure at least partially filling the opening.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1P are cross-sectional views of various stages of a process for forming a portion of a package structure, in accordance with some embodiments.

FIG. 1P-1 is a top view of a portion of a package structure, in accordance with some embodiments.

FIG. 2 is a cross-sectional view of a portion of a package structure, in accordance with some embodiments.

FIGS. 3A-3C are cross-sectional views of various stages of a process for forming a portion of a package structure, in accordance with some embodiments.

FIG. 4 is a cross-sectional view of a portion of a package structure, in accordance with some embodiments.

FIGS. 5A-5C are cross-sectional views of various stages of a process for forming a portion of a package structure, in accordance with some embodiments.

FIG. 6 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

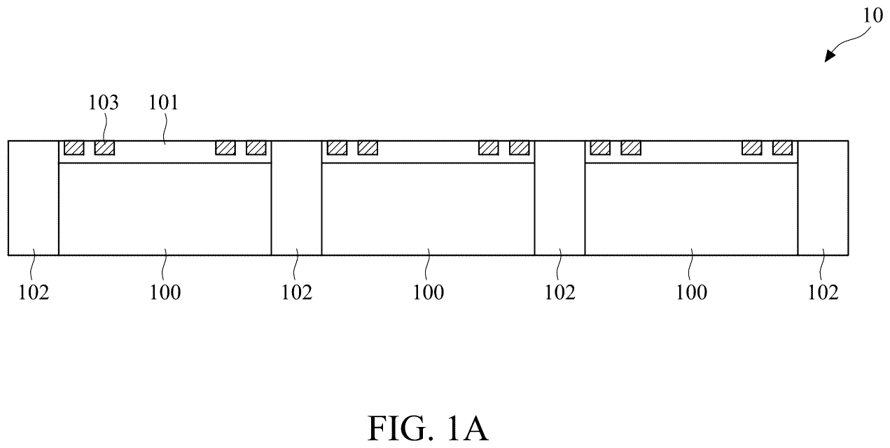

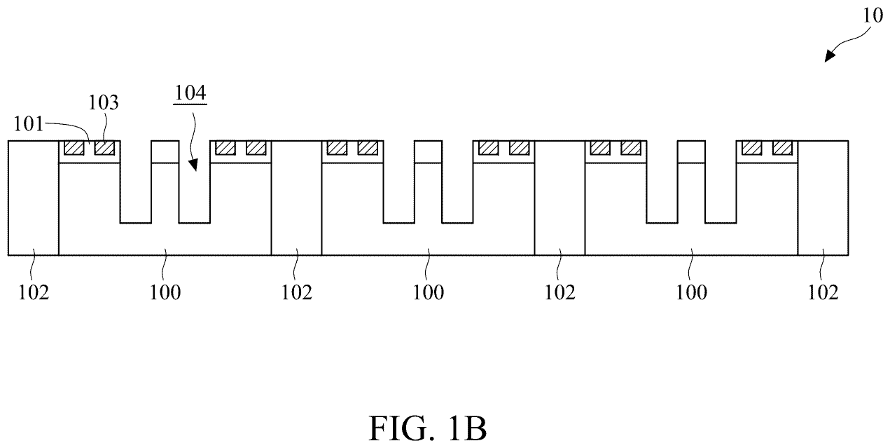

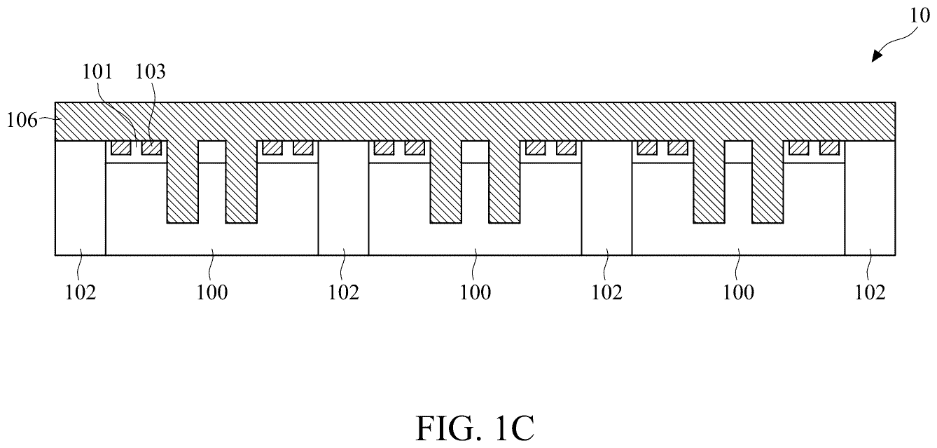

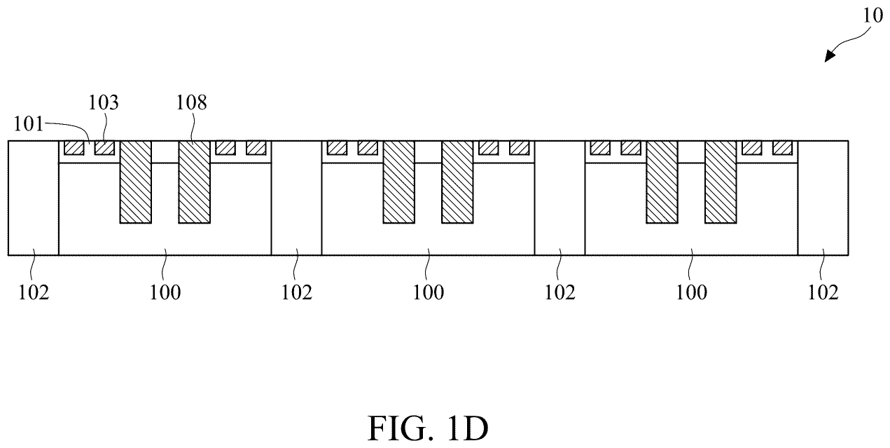

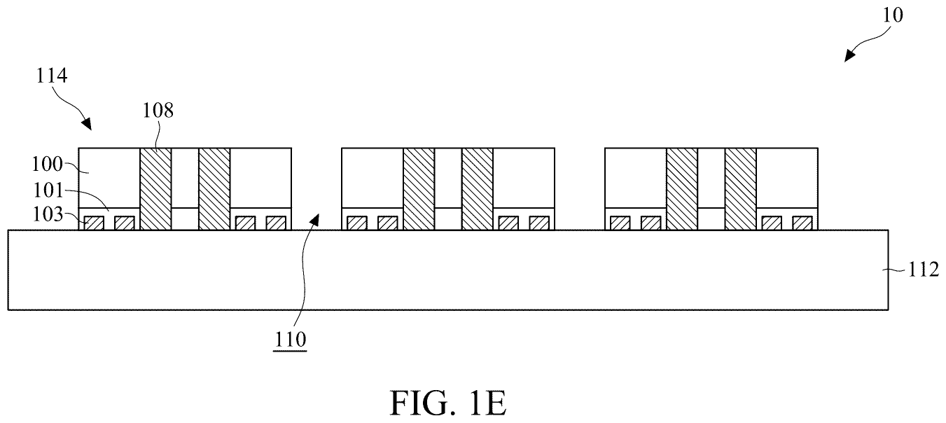

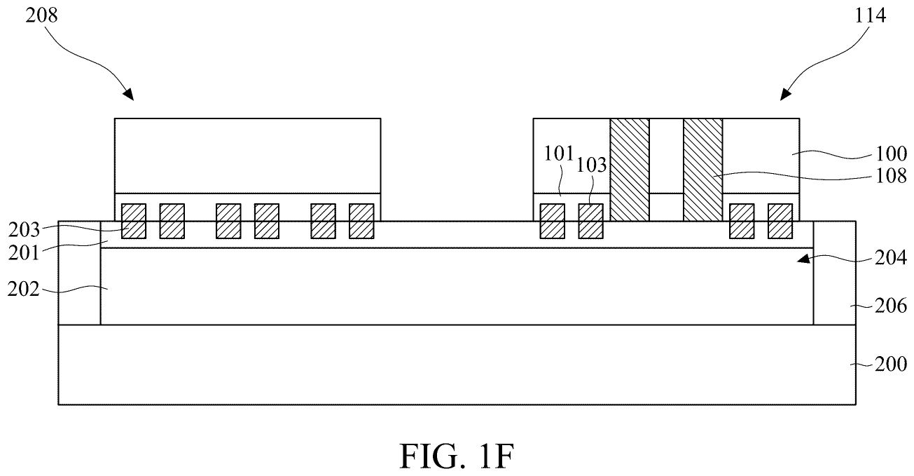

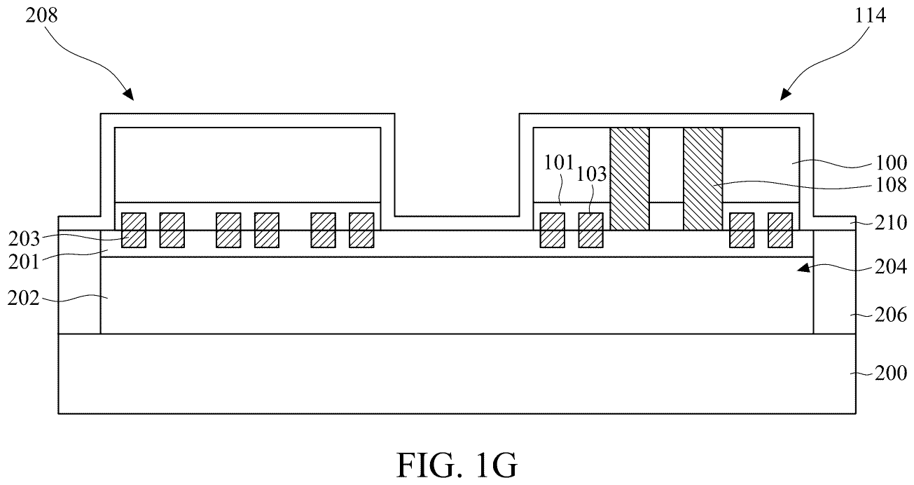

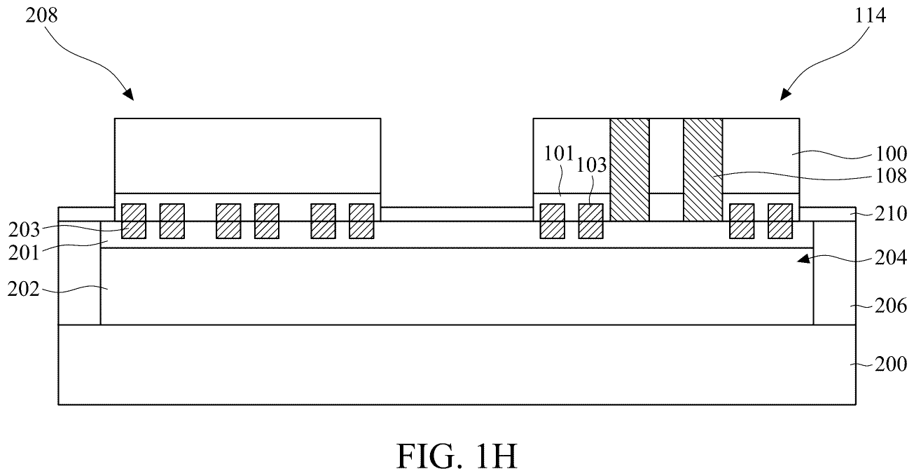

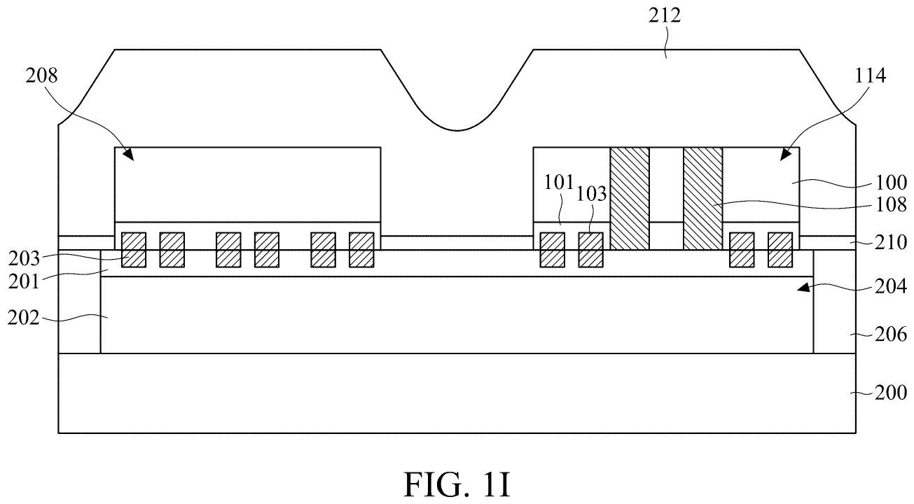

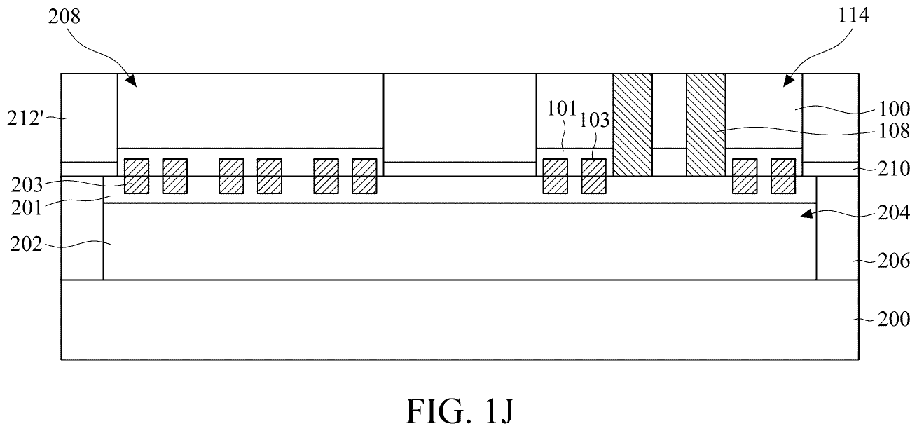

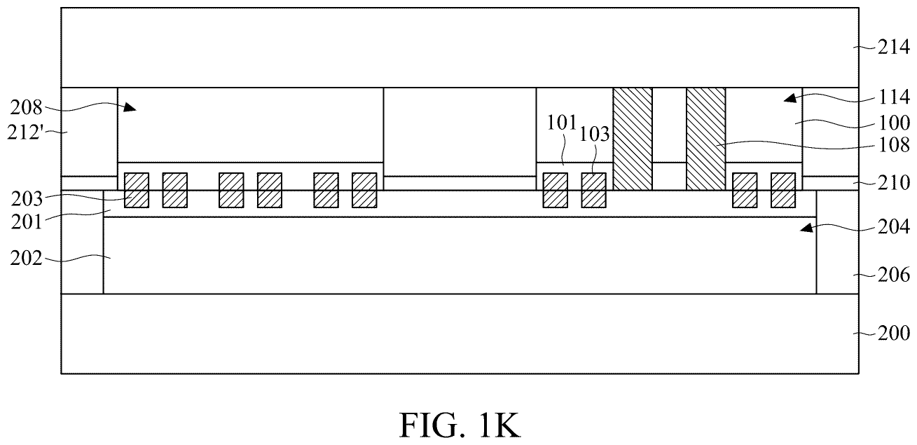

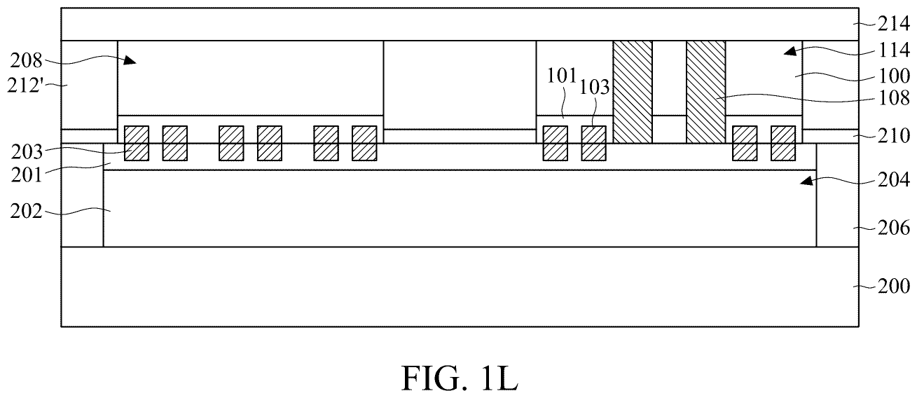

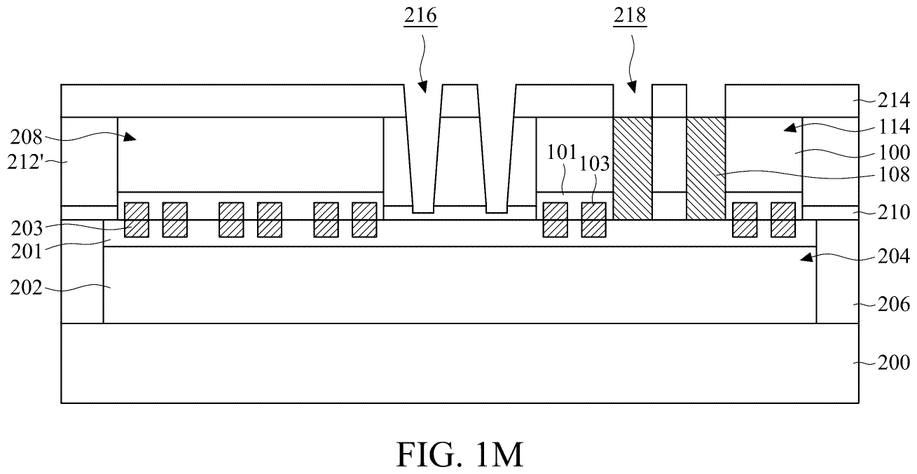

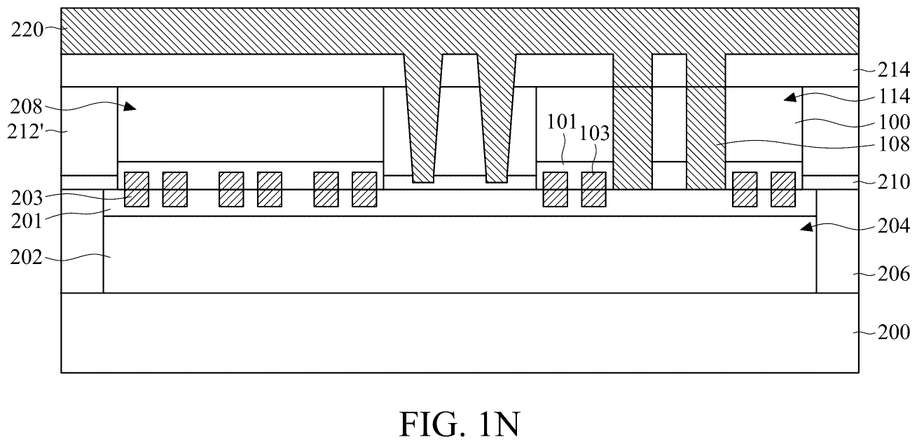

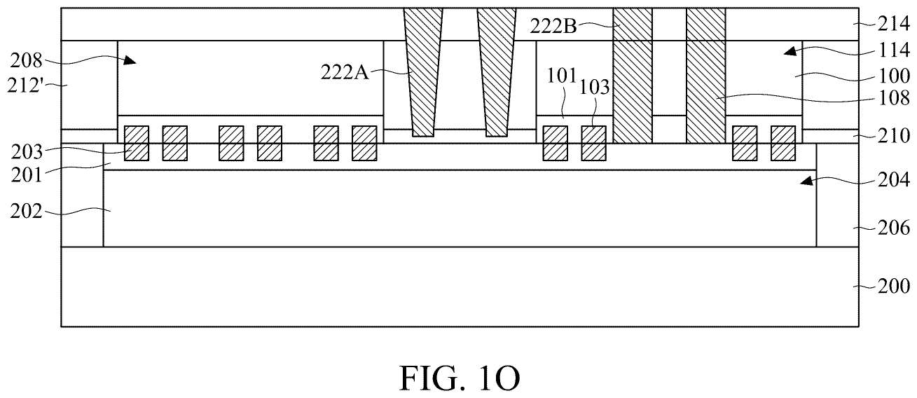

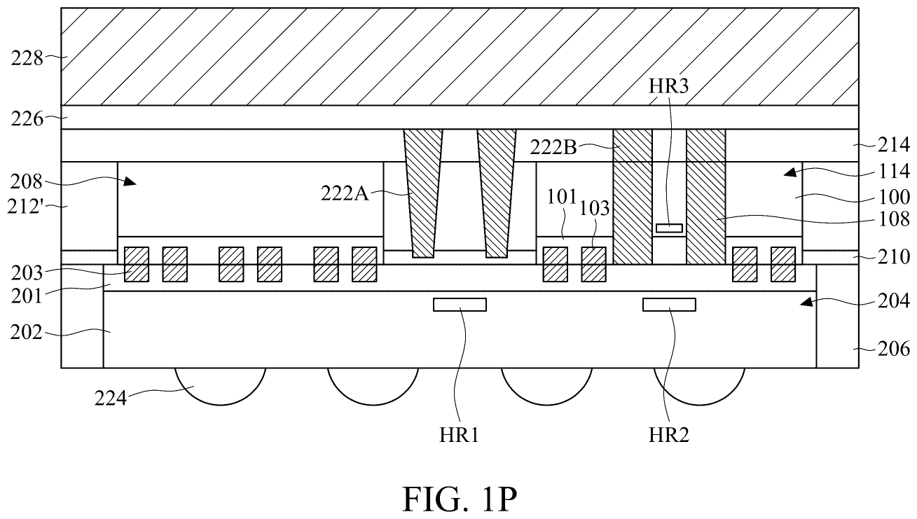

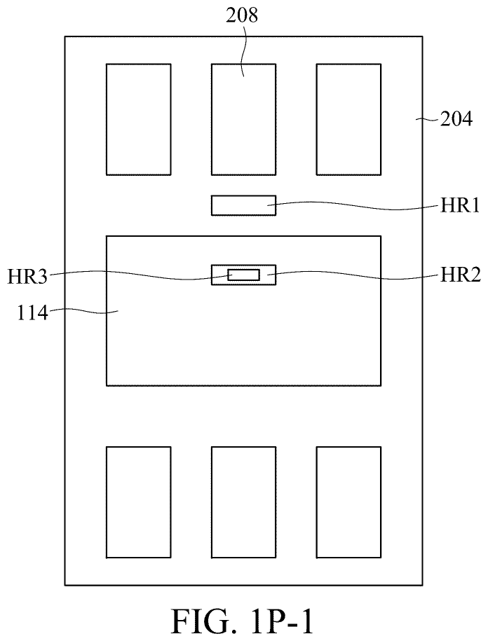

FIGS. 1A-1P are cross-sectional views of various stages of a process for forming a portion of a package structure, in accordance with some embodiments. As shown in FIG. 1A, a chip-containing structure 10 is received, in accordance with some embodiments. In some embodiments, the chip-containing structure 10 is a semiconductor wafer that includes multiple chip regions 100 that are surrounded by the scribe line region 102. After a subsequent sawing process, multiple semiconductor chips that are separated from each other may be obtained.

In some embodiments, the chip-containing structure 10 includes a semiconductor substrate. The semiconductor substrate may include silicon or another elementary semiconductor material such as germanium. The semiconductor substrate may be un-doped or doped (e.g., p-type, n-type, or a combination thereof). In some embodiments, the semiconductor substrate includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate includes a multi-layered structure. For example, the semiconductor substrate includes a silicon-germanium layer formed on a bulk silicon layer.

Various device elements are formed in or over the semiconductor substrate in the device regions 100. One of the device elements is shown in FIG. 1A. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The chip-containing structure 10 may include multiple interconnection structures such as front-side interconnection structures. Each of the interconnection structures includes multiple conductive features including metal bonding structures 103 that are surrounded by a dielectric portion 101. The dielectric portion 101 includes multiple dielectric layers. The conductive features may include conductive lines, conductive pads, conductive contacts, and conductive vias. In FIG. 1A, only the metal bonding structures 103 of the conductive features are shown. The dielectric portion 101 includes multiple dielectric layers.

The dielectric layers of the dielectric portion 101 may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features may be made of or include copper, tungsten, cobalt, aluminum, tantalum, gold, another suitable material, or a combination thereof. The formation of the interconnection structure may involve multiple deposition processes, patterning processes, planarization processes, another applicable process, or a combination thereof. In some embodiments, a CMP process is performed to ensure that the surface of the chip-containing structure 10 is highly planarized. The top surfaces of the metal bonding structures 103 and the dielectric portion 101 are level.

The device elements of the chip-containing structure 10 are interconnected by the interconnection structure to form integrated circuit devices, such as logic devices, memory devices (e.g., static random access memory, SRAM), radio frequency (RF) devices, input/output (I/O) devices, one or more other types of devices, or a combination thereof.

As shown in FIG. 1B, the chip-containing structure 10 is partially removed to form multiple openings 104 in the chip regions 100, in accordance with some embodiments. One or more photolithography processes and one or more etching processes may be used to form the openings. The openings 104 may have various top-view shapes, such as circular, square, oval, rectangular, or other suitable geometries. In some embodiments, the openings 104 are formed at the keep-out zones of the chip-containing structure 10. The device elements are spaced apart from the keep-out zones.

As shown in FIG. 1C, a thermal conductive layer 106 is formed over the chip-containing structure 10 to overfill the openings 104, in accordance with some embodiments. The thermal conductive layer 106 has a high thermal conductivity. The thermal conductive layer 106 may be made of or include a metal material, a ceramic material, a carbon-containing material, a semiconductor material, another suitable material, or a combination thereof. For instance, the thermal conductive layer 106 may be made of or include copper, aluminum, gold, beryllium oxide, hexagonal boron nitride (h-BN), aluminum nitride, graphite, graphene, carbon nanotube, silicon nitride, silicon carbide, another suitable material, or a combination thereof. The thermal conductive layer 106 may be formed using an electroplating process, an electrochemical plating process, a chemical vapor deposition (CVD) process, an atomic layer deposition (ALD) process, a flowable chemical vapor deposition (FCVD) process, another applicable process, or a combination thereof. In some embodiments, a seed layer is formed along the bottoms and sidewalls of the openings 104 before the formation of the thermal conductive layer 106.

As shown in FIG. 1D, the thermal conductive layer 106 is partially removed, in accordance with some embodiments. As a result, the remaining portions of the thermal conductive layer 106 in the openings 104 form multiple thermal conductive structures 108. In some embodiments, the thermal conductive structures 108 completely fill the openings 104. In some other embodiments, the thermal conductive structures 108 partially fill the openings 104. In some embodiments, the thermal conductive structures 108 are not electrically connected to the device elements formed in the chip-containing structure 114.

A planarization process may be used to partially remove the thermal conductive layer 106, thereby forming the thermal conductive structures 108. The planarization process may include a chemical mechanical polishing (CMP) process, a grinding process, a dry polishing process, an etching process, another applicable process, or a combination thereof.

Afterwards, the chip-containing structure 10 is partially removed and thinned, as shown in FIG. 1E in accordance with some embodiments. The scribe line region 102 is removed. In some embodiments, the ends of the thermal conductive structures 108 that are originally covered by the chip-containing structure 10 are exposed. As a result, multiple separate chip-containing structures 114 are obtained. Each of the chip-containing structures 114 may be a single semiconductor chip. A carrier substrate 112 is used to carry the chip-containing structures 114.

In some embodiments, the ends of the thermal conductive structures 108 that are originally covered by chip-containing structure 10 are exposed, as shown in FIG. 1E. The chip-containing structure 10 may be thinned using a CMP process, a grinding process, an etching process, another applicable process, or a combination thereof.

As shown in FIG. 1F, a reconstructed semiconductor wafer is provided or received. Multiple chip-containing structures 204 are disposed over a carrier substrate 200. In FIG. 1F, one of the chip-containing structures 204 is shown. The carrier substrate 200 is used as a support substrate during the fabrication process. In some embodiments, the carrier substrate 200 is a temporary support carrier and will be removed later.

The carrier substrate 200 may be made of or include a dielectric material, a semiconductor material, one or more other suitable materials, or a combination thereof. In some embodiments, the carrier substrate 200 is a dielectric substrate, such as a glass wafer. In some other embodiments, the carrier substrate 200 is a semiconductor substrate, such as a silicon wafer. The semiconductor substrate may be made of or include silicon, germanium, silicon germanium, another suitable semiconductor material, or a combination thereof.

As shown in FIG. 1F, a protective layer 206 is deposited over the carrier substrate 200 to laterally surround the chip-containing structures 204, in accordance with some embodiments. In some embodiments, each of the chip-containing structures 204 is a known good chip that is previously tested. The carrier substrate 200, the protective layer 206, and these chip-containing structures 204 together form a reconstructed wafer. Therefore, a subsequent wafer-level packaging process may be performed to form package structures.

The protective layer 206 may be made of or include a dielectric material. The dielectric material may include silicon oxide, silicon oxynitride, silicon carbide, carbon-containing silicon oxide, carbon-containing silicon oxynitride, carbon-containing silicon nitride, another suitable material, or a combination thereof.

In some embodiments, a protective material layer is deposited over the carrier substrate 200 to cover the chip-containing structures 204. The protective material layer may be deposited using a CVD process, an ALD process, an FCVD process, another applicable process, or a combination thereof. Afterwards, a planarization process such as a CMP process is used to partially remove the protective material layer. As a result, the remaining portion of the protective material layer forms the protective layer 206. In some embodiments, the top surfaces of the protective layer 206 and the chip-containing structures 204 are level.

Each of the chip-containing structures 204 may include a semiconductor substrate 202. The semiconductor substrate 202 may include silicon or another elementary semiconductor material such as germanium. The semiconductor substrate 202 may be un-doped or doped (e.g., p-type, n-type, or a combination thereof). In some embodiments, the semiconductor substrate 202 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 202 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 202 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 202 includes a multi-layered structure. For example, the semiconductor substrate 202 includes a silicon-germanium layer formed on a bulk silicon layer.

Various device elements are formed in or over the semiconductor substrate 202. Examples of the various device elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), diodes, or another suitable element. Various processes may be used to form the various device elements, including deposition, etching, implantation, photolithography, annealing, and other suitable processes.

The chip-containing structure 204 may include an interconnection structure such as a front-side interconnection structure. In some embodiments, the interconnection structure includes a dielectric portion 201. The interconnection structure also includes multiple conductive features including metal bonding structures 203 that are surrounded by the dielectric portion 201. The conductive features may include conductive lines, conductive pads, conductive contacts, and conductive vias. The dielectric portion 201 includes multiple dielectric layers. In FIG. 1F, only the metal bonding structures 203 of the conductive features are shown.

The dielectric layers of the dielectric portion 201 may be made of or include silicon oxide, silicon oxynitride, silicon nitride, carbon-containing silicon oxide, carbon-containing silicon nitride, carbon-containing silicon oxynitride, another suitable materials, or a combination thereof. The conductive features may be made of or include copper, tungsten, cobalt, aluminum, tantalum, gold, another suitable material, or a combination thereof. The formation of the interconnection structure may involve multiple deposition processes, patterning processes, planarization processes, another applicable process, or a combination thereof. In some embodiments, a CMP process is performed to ensure that the surface of the chip-containing structure 204 is highly planarized. The top surfaces of the metal bonding structures 203 and the dielectric portion 201 are level.

The device elements of the chip-containing structure 204 are interconnected by the interconnection structure to form integrated circuit devices, such as logic devices, memory devices (e.g., static random access memory, SRAM), radio frequency (RF) devices, input/output (I/O) devices, one or more other types of devices, or a combination thereof.

Afterwards, as shown in FIG. 1F, a chip-containing structure 114, picked up from the carrier substrate 112, and another chip-containing structure 208 are bonded to the chip-containing structure 204 through direct bonding, in accordance with some embodiments. The direct bonding may include dielectric-to-dielectric bonding and metal-to-metal bonding. In some embodiments, there is no tin-containing solder elements or solder bump formed between the lower chip-containing structure (i.e., the chip-containing structure 204) and the upper chip-containing structures (i.e., the chip-containing structures 114 and 208). In some embodiments, the bonding between the lower chip-containing structure (i.e., the chip-containing structure 204) and the upper chip-containing structures (i.e., the chip-containing structures 114 and 208) is a bumpless thermos-compression bonding.

In some embodiments, the chip-containing structure 114 is picked from the structure shown in FIG. 1E and placed directly on the dielectric portion 201 and the metal bonding structures 203 of the chip-containing structure 204. As a result, the dielectric portion 201 of the chip-containing structure 204 is in direct contact with the dielectric portion 101 of the chip-containing structure 114. The metal bonding structures 203 of the chip-containing structure 204 are in direct contact with the metal bonding structures 103 of the chip-containing structure 114.

Before the placing of the chip-containing structure 114, planarization processes are performed, so as to provide highly planarized bonding surfaces. In some embodiments, there is no gap between the dielectric portions 101 and 201. In some embodiments, there is no gap between the metal bonding structures 103 and 203. In some embodiments, a thermal operation is then used to enhance the bonding between the metal bonding structures 103 and 203. The temperature of the thermal operation may within a range from about 100 degrees C to about 500 degrees C. In some embodiments, a thermos-compression process is used to enhance the bonding between the chip-containing structures 114 and 204. Similarly, the chip-containing structure 208 is also bonded to the chip-containing structure 204 through dielectric-to-dielectric bonding and metal-to-metal bonding.

As shown in FIG. 1G, an etch stop layer 201 is deposited over the chip-containing structures 114, 208 and 204, in accordance with some embodiments. The etch stop layer 201 may be made of or include silicon nitride, silicon oxynitride, carbon-containing silicon nitride, carbon-containing silicon oxynitride, another suitable material, or a combination thereof. The etch stop layer 210 may be deposited using a CVD process or the like.

As shown in FIG. 1H, the etch stop layer 210 is partially removed, in accordance with some embodiments. As a result, the tops of the chip-containing structures 114 and 208 are exposed. The upper portions of the sidewalls of the chip-containing structures 114 and 208 are also exposed. One or more photolithography processes and one or more etching processes may be used to partial remove the etch stop layer 210.

As shown in FIG. 1I, a protective material layer 212 is deposited over the chip-containing structures 114, 208 and 204 and the etch stop layer 210, in accordance with some embodiments. The protective material layer 212 may be made of or include silicon oxide, silicon oxynitride, silicon carbide, carbon-containing silicon oxide, carbon-containing silicon oxynitride, carbon-containing silicon nitride, another suitable material, or a combination thereof. The protective material layer 212 may be deposited using a CVD process, an ALD process, an FCVD process, another applicable process, or a combination thereof.

As shown in FIG. 1J, a planarization process is used to partially remove the protective material layer 212. As a result, the remaining portion of the protective material layer 212 forms a protective layer 212′. In some embodiments, the top surface of the protective layer 212′ and the surfaces of the chip-containing structures 114 and 208 are level. The planarization process may include a CMP process, a grinding process, an etching process, another applicable process, or a combination thereof.

As shown in FIG. 1K, a carrier substrate 214 is attached to the structure shown in FIG. 1J, in accordance with some embodiments. The carrier substrate 214 may be a semiconductor substrate such as a silicon wafer. Alternatively, the carrier substrate 214 may be a dielectric substrate such as a glass wafer.

As shown in FIG. 1L, the carrier substrate 214 is thinned, in accordance with some embodiments. The carrier substrate 214 may be thinned using a grinding process, a CMP process, an etching process, another applicable process, or a combination thereof.

As shown in FIG. 1M, the carrier substrate 214 and the protective layer 212′ are partially removed in sequence, in accordance with some embodiments. As a result, openings 216 that expose the protective layer 212′ and the etch stop layer 210 are formed. Openings 218 that expose the thermal conductive structures 108 formed in the chip-containing structure 114 are also formed. One or more photolithography processes and one or more etching processes may be used to form the openings 216 and 218. In some embodiments, the openings 216 and 218 are simultaneously formed. In some other embodiments, the openings 216 and 218 are sequentially formed. For example, the openings 216 may be formed before the openings 218.

As shown in FIG. 1N, a thermal conductive layer 220 is formed to overfill the openings 216 and 218, in accordance with some embodiments. The thermal conductive layer 220 has a high thermal conductivity. The thermal conductive layer 220 may be made of or include a metal material, a ceramic material, a carbon-containing material, a semiconductor material, another suitable material, or a combination thereof. For instance, the thermal conductive layer 220 may be made of or include copper, aluminum, gold, beryllium oxide, hexagonal boron nitride (h-BN), aluminum nitride, graphite, graphene, carbon nanotube, silicon nitride, silicon carbide, another suitable material, or a combination thereof. In some embodiments, the thermal conductive layer 220 and the thermal conductive structures 108 are made of the same material. In some other embodiments, the thermal conductive layer 220 and the thermal conductive structures 108 are made of different materials.

The thermal conductive layer 220 may be formed using an electroplating process, an electrochemical plating process, a chemical vapor deposition (CVD) process, an atomic layer deposition (ALD) process, a flowable chemical vapor deposition (FCVD) process, another applicable process, or a combination thereof. In some embodiments, a seed layer is formed along the bottoms and sidewalls of the openings 216 and 218 before the formation of the thermal conductive layer 220.

As shown in FIG. 1O, the thermal conductive layer 220 is partially removed, in accordance with some embodiments. As a result, the remaining portions of the thermal conductive layer 220 in the openings 216 and 218 form thermal conductive structures 222A and 222B, respectively. In some embodiments, the thermal conductive structures 222A and 222B completely fill the openings 216 and 218. In some other embodiments, the thermal conductive structures 222A and 222B partially fill the openings 216 and 218. In some embodiments, the thermal conductive structures 222A are not electrically connected to the device elements formed in the chip-containing structures 114 and 204.

A planarization process may be used to partially remove the thermal conductive layer 220, thereby forming the thermal conductive structures 222A and 222B. The planarization process may include a chemical mechanical polishing (CMP) process, a grinding process, a dry polishing process, an etching process, another applicable process, or a combination thereof.

As shown in FIG. 1P, the carrier substrate 200 is removed, and multiple conductive bumps 224 are formed below the chip-containing structure 204, in accordance with some embodiments. A redistribution structure may be formed below the chip-containing structure 204 after the removal of the carrier substrate 200 and before the formation of the conductive bumps 224. The redistribution structure may include multiple insulating layers and multiple conductive features for routing.

Afterwards, in some embodiments, a sawing process is used to separate the structure into multiple package structures. One of the package structures is shown in FIG. 1P. In some embodiments, the chip-containing structure 204 is originally a portion of a reconstructed semiconductor wafer. After the sawing process, the chip-containing structure 204 shown in FIG. 1P may be a single semiconductor chip. The package structure shown in FIG. 1P may function as a system on integrated chips (SoIC) that may further be integrated into another package structure.

As shown in FIG. 1P, a thermal conductive lid 228 is then disposed over the carrier substrate 214 and the thermal conductive structures 222A and 222B of the package structure, in accordance with some embodiments. A thermal interface element 226 may be formed between the thermal conductive lid 228 and the carrier substrate 214. The thermal conductive lid 228 may be made of or include copper, aluminum, steel, titanium, nickel, gold, silver, another suitable material, or a combination thereof. The thermal interface element 226 may be made of or include a metal material. In some embodiments, the thermal interface element 226 is made of or include a metal material that has a low melting point and has a low stress. The thermal interface element 226 may be made of or include an indium-based material, a gallium-based material, another suitable material, or a combination thereof.

FIG. 1P-1 is a top view of a portion of a package structure, in accordance with some embodiments. In some embodiments, FIG. 1P-1 is a top view of the structure shown in FIG. 1P. As shown in FIGS. 1P and 1P-1, in some embodiments, during the operation of the package structure, certain regions may experience increased heat accumulation, creating hot spot regions such as the hot spot regions HR1, HR2, and HR3. The thermal conductive structures 222A, 222B, and 108 enhance the heat dissipation path between the thermal conductive lid 228 and the hot spot regions HR1, HR2, and HR3. This allows the device elements within the package structure to operate at lower temperatures, significantly improving the performance and reliability of the package structure.

In some embodiments, the thermal conductive structures 222A are spaced apart from the chip-containing structure 204 by the etch stop layer 210. However, embodiments of the disclosure are not limited thereto. Many variations and/or modifications can be made to embodiments of the disclosure. In some other embodiments, the thermal conductive structures 222A are in direct contact with the chip-containing structure 204.

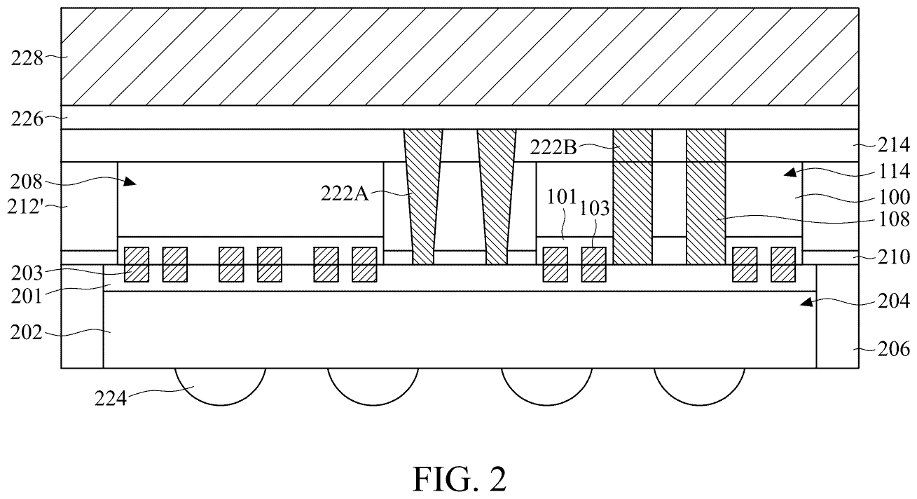

FIG. 2 is a cross-sectional view of a portion of a package structure, in accordance with some embodiments. In some embodiments, the thermal conductive structures 222A penetrate through the etch stop layer 210. In some embodiments, the thermal conductive structures 222A are in direct contact with the chip-containing structure 204. In some embodiments, the thermal conductive structures 222A further extend into the dielectric portion 201 of the chip-containing structure 204.

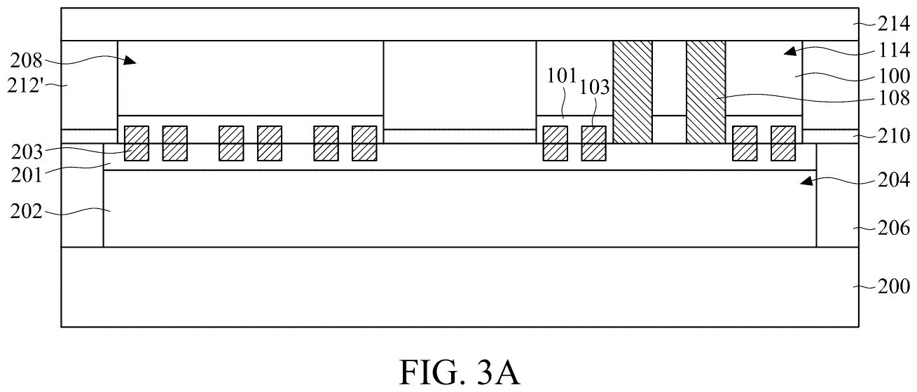

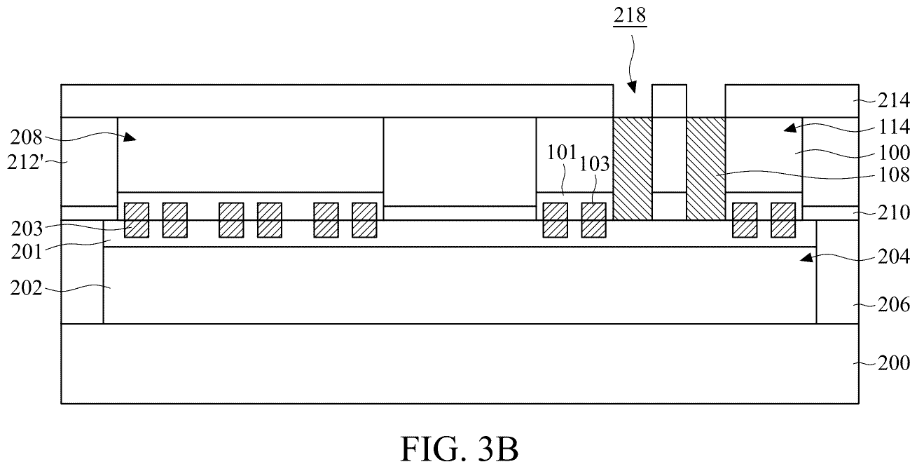

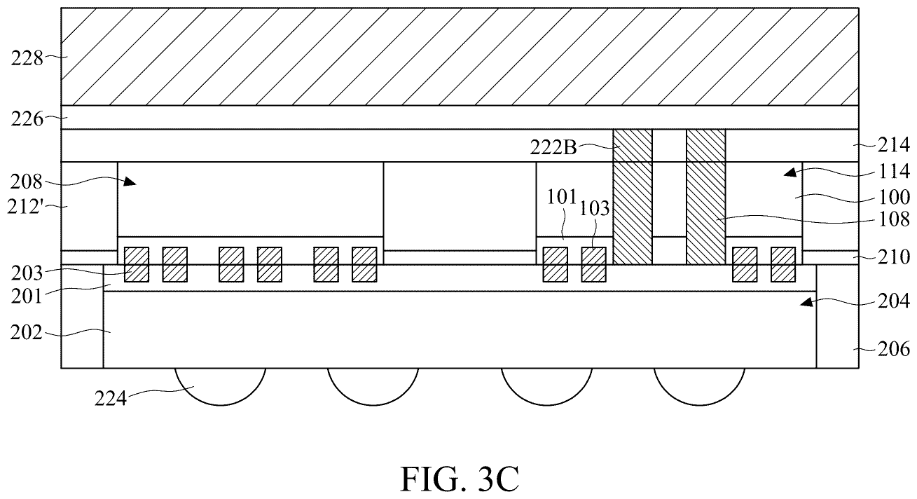

Many variations and/or modifications can be made to embodiments of the disclosure. FIGS. 3A-3C are cross-sectional views of various stages of a process for forming a portion of a package structure, in accordance with some embodiments. As shown in FIG. 3A, a structure that is the same as or similar to that shown in FIG. 1L is formed.

As shown in FIG. 3B, the carrier substrate 214 is partially removed to form the openings 218 expose the thermal conductive structures 108, in accordance with some embodiments. Afterwards, the processes that are similar to those illustrated in FIGS. 1N-1P are performed. As a result, the structure shown in FIG. 3C is formed, in accordance with some embodiments.

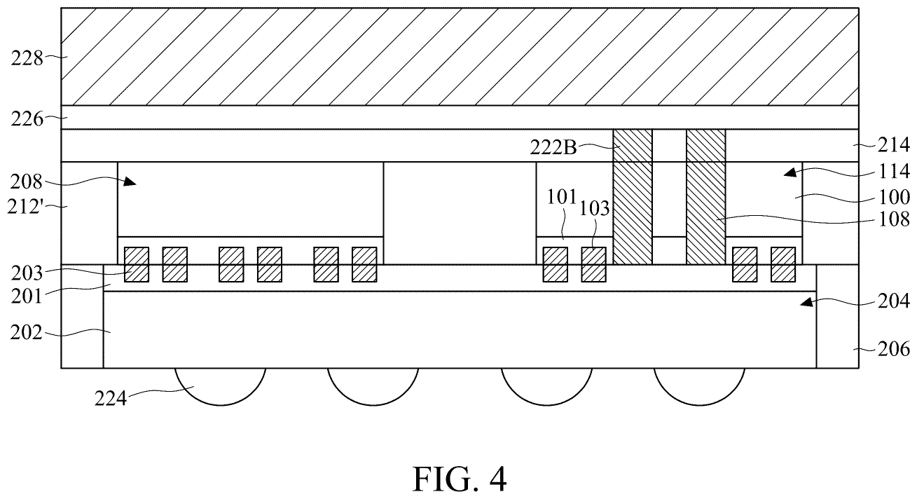

Many variations and/or modifications can be made to embodiments of the disclosure. FIG. 4 is a cross-sectional view of a portion of a package structure, in accordance with some embodiments. A structure that is similar to that shown in FIG. 3C is formed. In some embodiments, no etch stop layer is formed before the formation of the protective layer 212′.

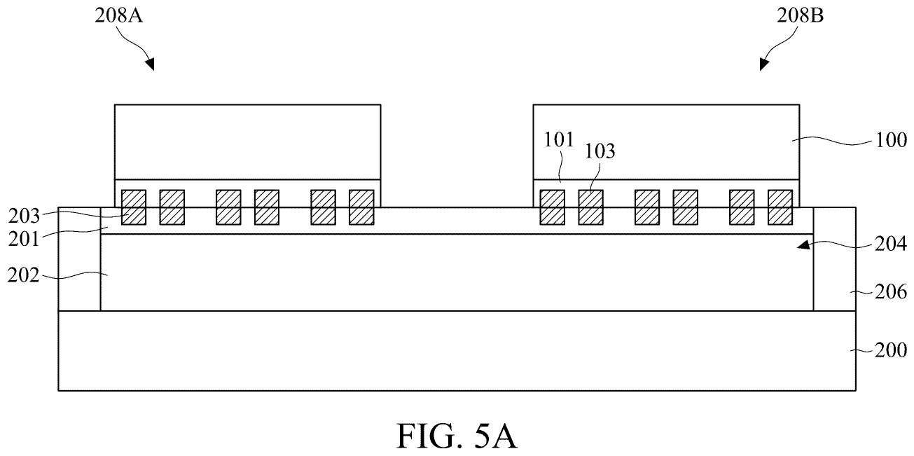

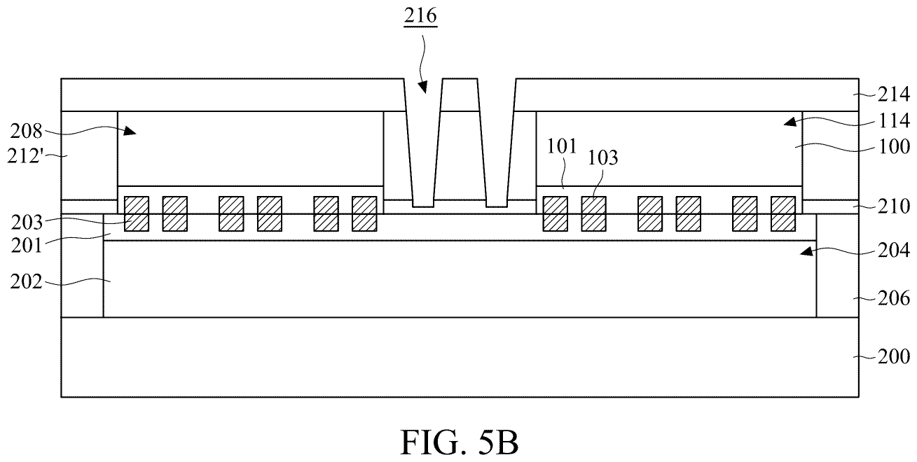

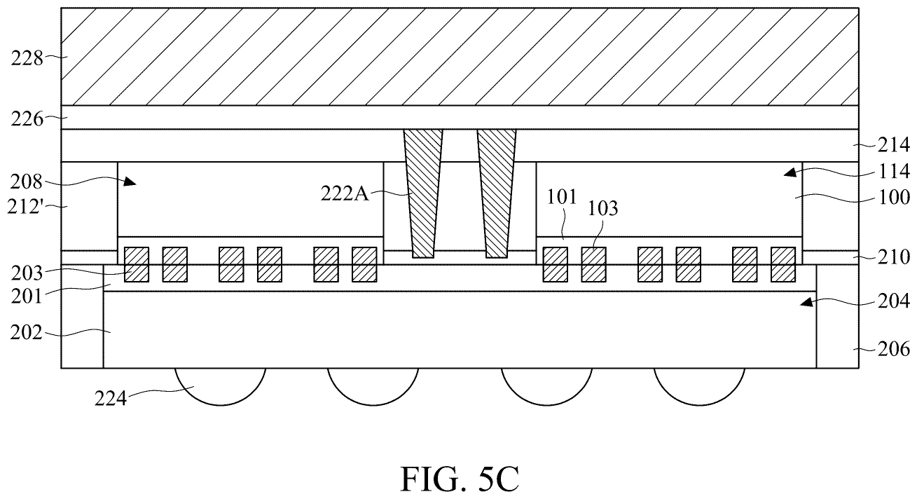

Many variations and/or modifications can be made to embodiments of the disclosure. FIGS. 5A-5C are cross-sectional views of various stages of a process for forming a portion of a package structure, in accordance with some embodiments. In some embodiments, a structure that is similar to that shown in FIG. 1F is formed. In some embodiments, chip-containing structures 208A and 208B are bonded to the chip-containing structure 204 through dielectric-to-dielectric bonding and metal-to-metal bonding. Unlike the embodiments shown in FIG. 1F, in some embodiments, no thermal conductive structure is formed in the chip-containing structure 208B.

As shown in FIG. 5B, the carrier substrate 214 and the protective layer 212′ are partially removed to form the openings 216, in accordance with some embodiments. Afterwards, the processes that are similar to those illustrated in FIGS. 1N-1P are performed. As a result, the structure shown in FIG. 5C is formed, in accordance with some embodiments.

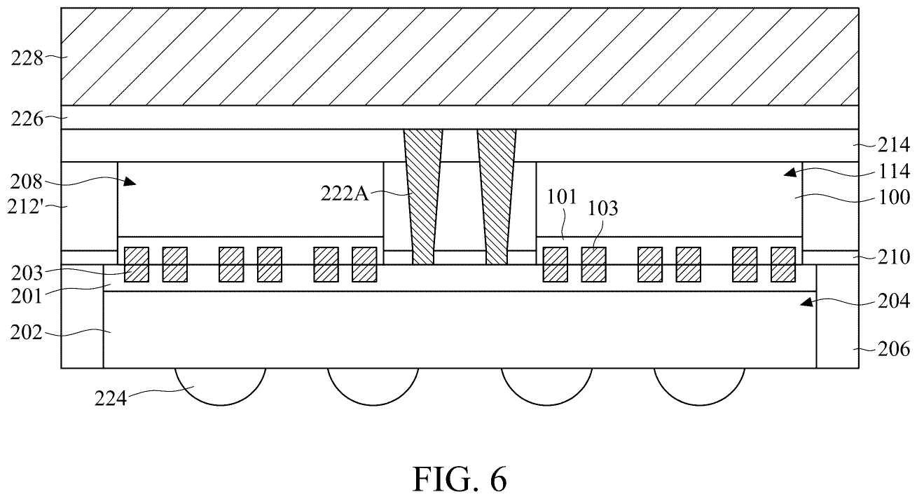

Many variations and/or modifications can be made to embodiments of the disclosure. FIG. 6 is a cross-sectional view of a portion of a package structure, in accordance with some embodiments. In some embodiments, a structure that is similar to that shown in FIG. 5C is formed. In some embodiments, the thermal conductive structures 222A penetrate through the etch stop layer 210. In some embodiments, the thermal conductive structures 222A are in direct contact with the chip-containing structure 204. In some embodiments, the thermal conductive structures 222A further extend into the dielectric portion 201 of the chip-containing structure 204.

Embodiments of the disclosure form a package structure with multiple bonded chip-containing structures. One or more thermal conductive structures are formed within one or more of the chip-containing structures and/or within a protective layer around the chip-containing structures. The thermal conductive structures may enhance the heat dissipation path to the hot spot regions within the package structure. This allows the device elements within the package structure to operate at lower temperatures, significantly improving the performance and reliability of the package structure.

In accordance with some embodiments, a method for forming a package structure is provided. The method includes disposing an upper chip-containing structure over a lower chip-containing structure and forming a protective layer laterally surrounding the upper chip-containing structure. The method also includes partially removing the protective layer to form an opening extending towards the lower chip-containing structure. The method further includes forming a thermal conductive structure at least partially filling the opening.

In accordance with some embodiments, a method for forming a package structure is provided. The method includes disposing an upper chip-containing structure over a lower chip-containing structure. A thermal conductive structure extends into the upper chip-containing structure from a surface of the upper chip-containing structure. The method also includes forming a protective layer laterally surrounding the upper chip-containing structure. The method further includes disposing a thermal conductive lid over the upper chip-containing structure and the thermal conductive structure.

In accordance with some embodiments, a package structure is provided. The package structure includes a lower chip-containing structure and a thermal conductive lid over the lower chip-containing structure. The package structure also includes an upper chip-containing structure between the lower chip-containing structure and the thermal conductive lid. The package structure further includes a protective layer laterally surrounding the upper chip-containing structure and a thermal conductive structure between the lower chip-containing structure and the thermal conductive lid. The protective layer laterally surrounds a lower portion of the thermal conductive structure. The thermal conductive structure is closer to the thermal conductive lid than the upper chip-containing structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
disposing an upper chip-containing structure over a lower chip-containing structure;
forming a protective layer laterally surrounding the upper chip-containing structure;
partially removing the protective layer to form an opening extending towards the lower chip-containing structure; and
forming a thermal conductive structure at least partially filling the opening.

2. The method for forming a package structure as claimed in claim 1, further comprising:
disposing a carrier substrate over the protective layer before the protective layer is partially removed to form the opening; and
partially removing the carrier substrate before the opening is formed.

3. The method for forming a package structure as claimed in claim 2, further comprising:
disposing a thermal conductive lid over the carrier substrate and the thermal conductive structure.

4. The method for forming a package structure as claimed in claim 2, further comprising:
forming a second opening in the carrier substrate, wherein the second opening exposes a second thermal conductive structure extending into the upper chip-containing structure.

5. The method for forming a package structure as claimed in claim 4, further comprising:
forming a thermal conductive layer over the carrier substrate to fill the opening and the second opening; and
planarizing the thermal conductive layer, wherein a first remaining portion of the thermal conductive layer in the opening forms the thermal conductive structure, and a second remaining portion of the thermal conductive layer in the second opening forms a third thermal conductive structure over the second thermal conductive structure.

6. The method for forming a package structure as claimed in claim 1, further comprising:
forming a thermal conductive layer over the protective layer to fill the opening; and
planarizing the thermal conductive layer, wherein a remaining portion of the thermal conductive layer forms the thermal conductive structure.

7. The method for forming a package structure as claimed in claim 1, further comprising:
forming an etch stop layer over the upper chip-containing structure and the lower chip-containing structure before the protective layer is formed, wherein the opening exposes the etch stop layer after the protective layer is partially removed.

8. The method for forming a package structure as claimed in claim 7, further comprising:
partially removing the etch stop layer to expose a top surface and a sidewall of the upper chip-containing structure before the protective layer is formed.

9. The method for forming a package structure as claimed in claim 1, further comprising:
receiving a semiconductor wafer, wherein the semiconductor wafer has a plurality of chip regions and a scribe line region surrounding the chip regions;
partially removing the semiconductor wafer to form a plurality of openings in the chip regions;
forming a plurality of second thermal conductive structures in the openings; and
removing the scribe line region to obtain a plurality of semiconductor chips that are separated from each other, wherein one of the semiconductor chips is the upper chip-containing structure.

10. The method for forming a package structure as claimed in claim 9, further comprising:
thinning the semiconductor wafer to expose ends of the second thermal conductive structures that are originally covered by the semiconductor wafer.

11. A method for forming a package structure, comprising:
disposing an upper chip-containing structure over a lower chip-containing structure, wherein a thermal conductive structure extends into the upper chip-containing structure from a surface of the upper chip-containing structure;
forming a protective layer laterally surrounding the upper chip-containing structure; and
disposing a thermal conductive lid over the upper chip-containing structure and the thermal conductive structure.

12. The method for forming a package structure as claimed in claim 11, further comprising:
disposing a carrier substrate over the protective layer and the upper chip-containing structure;
forming an opening in the carrier substrate to expose the thermal conductive structure; and
forming a second thermal conductive structure in the opening before the thermal conductive lid is disposed.

13. The method for forming a package structure as claimed in claim 12, further comprising:
thinning the carrier substrate before the opening is formed.

14. The method for forming a package structure as claimed in claim 12, further comprising:
partially removing the carrier substrate and the protective layer to form a second opening extending towards the lower chip-containing structure before the thermal conductive lid is disposed; and
forming a third thermal conductive structure at least partially filling the second opening.

15. The method for forming a package structure as claimed in claim 14, further comprising:
forming a thermal conductive layer over the carrier substrate to overfill the opening and the second opening; and
partially removing the thermal conductive layer by planarizing the thermal conductive layer, wherein a first remaining portion of the thermal conductive layer forms the second thermal conductive structure, and a second remaining portion of the thermal conductive layer forms the third thermal conductive structure.

16. A package structure, comprising:
a lower chip-containing structure;
a thermal conductive lid over the lower chip-containing structure;
an upper chip-containing structure between the lower chip-containing structure and the thermal conductive lid;
a protective layer laterally surrounding the upper chip-containing structure; and
a thermal conductive structure between the lower chip-containing structure and the thermal conductive lid, wherein the protective layer laterally surrounds a lower portion of the thermal conductive structure, and the thermal conductive structure is closer to the thermal conductive lid than the upper chip-containing structure.

17. The package structure as claimed in claim 16, further comprising:
a carrier substrate between the protective layer and the thermal conductive lid, wherein the thermal conductive structure penetrates through the carrier substrate.

18. The package structure as claimed in claim 17, wherein the thermal conductive structure extends into the protective layer.

19. The package structure as claimed in claim 17, wherein the thermal conductive structure extends into the upper chip-containing structure.

20. The package structure as claimed in claim 16, wherein the thermal conductive structure is not electrically connected to device elements of the lower chip-containing structure and the upper chip-containing structure.
